(19) United States
(12) Patent Application Publication
(10) Pub. No.: US 2007/0009659 A1
(43) Pub. Date: Jan. 11, 2007

(54) Process for the self-limiting deposition of one or more monolayers

(76) Inventors: Peter Baumann, Aachen (DE); Johannes Lindner, Roetgen (DE); Marcus Schumacher, Kerpen (DE)

Correspondence Address: ST. ONGE STEWARD JOHNSTON & REENS, LLC, 986 BEDFORD STREET, STAMFORD, CT, 06905-5619, US

(21) Appl. No.: 11/455,372

(22) Filed: Jun. 19, 2006

Related U.S. Application Data
(63) Continuation-in-part of application No. PCT/EP05/56553, filed on Dec. 7, 2005.

(30) Foreign Application Priority Data
Dec. 18, 2004 (DE) 10 2004 061094.0

(51) Int. Cl. C23C 16/00

(52) U.S. Cl. 427/248.1; 427/255.23; 427/255.7; 427/255.6

(57) ABSTRACT

The invention relates to a process for depositing at least one layer, which contains at least one first component, on at least one substrate in a process chamber, first and second starting materials, of which at least the first starting material contains the first component, being introduced in gaseous form into the process chamber in a cyclically alternating manner, in order to deposit substantially only one layer at a time of the first component with every cycle. In order to increase the spectrum of suitable staring materials that are available the invention proposes that a first starting material which does not intrinsically allow itself to be deposited in a self-limiting manner, is used and, a limiter formed of a hydrocarbon is introduced into the process chamber in such a way that the depositing of the first component on the substrate automatically ends after completion of the first layer.

### FIELD OF THE INVENTION

The invention relates to a process for depositing at least one layer, which contains at least one first component, onto at least one substrate in a process chamber, first and second starting materials, of which at least the first starting material contains the first component, being introduced in gaseous form into the process chamber in a cyclically alternating manner, in order to deposit substantially only one layer at a time, in particular a monolayer, of the first component with every cycle.

### BACKGROUND OF THE INVENTION

In order to ensure the further development of electronic components, for example for CMOS, DRAM applications, high-k materials are sought as alternatives to SiO₂ as a dielectric. As candidates for this, aluminum oxide, hafnium oxide or praseodymium oxide, but specifically also multi-component oxides, are of especially great interest, since they have outstanding properties with regard to the dielectric constant and leakage currents. Recent findings even demonstrate improved material properties by lamination or mixing of these metal oxides with one another or, to improve the thermal stability, also by adding silicon. Polysilicon will also have to be replaced by new metal-based electrodes. The industrial fabrication of such material systems requires a depositing technology that ensures efficient, reproducible and uniform deposition of films with well-defined intermediate layers and high conformality on structured substances. MBE does not achieve conformal edge coverage when depositing thin layers, while MOCVD and ALD processes ensure good coverage when depositing on structured substrates.

In the case of conventional MOCVD, the poor atomic precision causes inadequacies with regard to layer thickness control, for example when depositing nanolaminates. In addition, inadequate edge coverage is often reported in the case of conventional MOCVD when depositing on highly structured substrates.

ALD is a special form of MOCVD and is based in principle on alternating, self-limiting chemical reactions for the successive deposition of monolayers. High conformality can be achieved thereby when depositing on structured substrates. However, ALD processes resort to a very small number of available precursors, which are often based on chlorine compounds. The alternating introduction of gaseous H₂O, for example, into the process chamber as an oxidant thereby produces HCL as a byproduct, which however is quite difficult to handle safely as a waste gas byproduct.

Generic processes are described in particular by U.S. Pat. No. 6,200,893, U.S. Pat. No. 6,451,695, U.S. Pat. No. 6,638,862, U.S. Pat. No. 6,602,784, U.S. Pat. No. 6,475,910, U.S. Pat. No. 6,630,401, U.S. Pat. No. 6,305,314, U.S. Pat. No. 6,451,119, U.S. Pat. No. 6,540,838 and U.S. Pat. No. 6,638,859.

DE 102 00 4015174 describes a process by which monolayers can be deposited by alternately introducing a reactive starting material with a chemically reactive gas.

DE 102 12 923 A1 describes a process by which solid starting materials are brought into the gas phase and introduced into a process chamber as a gas.

DE 100 57 491 describes a process by which a substance in the form of a liquid is vaporized by pulsed introduction into a heated gas volume.

On the basis of the prior art cited at the beginning, an object of the invention is to increase the spectrum of suitable starting materials that are available.

### SUMMARY OF THE INVENTION

The object is achieved by the invention specified in the claims, each of the formally subsidiary or subordinate claims proposing an independent solution and it being possible for any claim to be combined with any other claim.

### DETAILED DESCRIPTION OF THE INVENTION

Claim 1 provides first and foremost that, at the same time as or at a different time from the first starting material, a limiter is introduced into the process chamber in such a way that the depositing of the first component on the substrate automatically ends after completion of the layer. This makes it possible to carry out the generic process even with those starting materials that do not intrinsically allow themselves to be deposited in a self-limiting manner, or only within an inadequately narrow process window. As a result, the spectrum of available starting materials has been widened considerably. The limiter is preferably a suitable liquid, solid or gaseous material which interacts with the first starting material or a constituent of the first starting material in such a way that the first starting material is deposited on the substrate only as a single layer, preferably as a monolayer. However, it is also provided that the limiter is not introduced into the process chamber together with the first starting material but during another process step. It may in this case act with a surface passivation effect, so that the growth of the first component merely takes place two-dimensionally. It is also possible to introduce the starting material into the process chamber together with a chemically reactive material. The chemically reactive material interacts with the first component or with the limiter in such a way that, after completion of the cycle, a new monolayer of the first component can be deposited. It is therefore possible to deposit a layer by a monolayer being cyclically deposited onto the previously deposited monolayer. The limiter has in this case the task of restricting the layer growth to a monolayer. In a development of the invention, it is provided that the layer consists of a number of components. Here, too, the individual components are introduced into the process chamber at successive times. It is however also possible to introduce a number of components into the process chamber at the same time, but in that case measures by which the layer growth per cycle is restricted to a monolayer are also taken. With the limiter, the degree of deposition can be controlled. This takes place in particular during the growth of a single- or multi-component layer on a planar and/or highly structured substrate. A number of substrates may be disposed in the process chamber. They may lie next to one another or one on top of the other. The substrates may be aligned in parallel with one another. They may, however, also be inclined in relation to one another. Three different substances are preferably used: a first starting material, containing the first component, a limiter and a reactive gas. These substances are introduced into the process chamber in each case one after the other in a cyclical sequence, so that only one monolayer is deposited during each cycle. Between the individual process steps or process cycles, the process chamber may be purged with an inert gas. The process chamber may be evacuated between the individual process steps or the process cycles. The starting materials used preferably contains a metal. A metalorganic compound may be used. The limiters are preferably hydrocarbons. The pairing of ruthenium and octane or isooctane are preferred as limiter. The process temperature may lie between 200° C. and 700° C. However, it may also lie only between 200° C. and 500° C. The pressure inside the process chamber lies below 100 mbar and preferably in the range between 0.1 and ten torr. However, the pressure may also vary only in a range between one and three torr. It is also possible for a number of starting materials to be used, the starting materials respectively containing a second or third component, which components are incorporated in the layer, so that a multicomponent layer or layer sequence is deposited. The starting materials may be in the form of solids or liquids. They can be transformed into the gas phase in special vaporizing chambers. They can be kept there in solution with the limiter. An at least 0.01 molar solution of the substance in a solvent may be used. In particular, an at least 0.01 molar solution of the substance in a solvent may be used. In particular, a 0.05 to 1 molar solution or a 0.05 to 0.1 molar solution may be used. Oxygen compounds or nitrogen compounds come into consideration as the chemically reactive gases. In particular, O₂, O₃, N₂O, H₂O or NH₃. The vaporization takes place in a special vaporizing chamber, in which there is a heated carrier gas. The liquid starting material is atomized into this heated gas. The heat required for vaporization is extracted from the gas phase. The vaporization consequently takes place without contact. The deposited layers may contain metal, oxygen, nitrogen or carbon. They are preferably insulating, passivating, semiconducting or electrically conducting layers. A multiplicity of layers are preferably deposited one on top of the other, respectively produced by depositing monolayer on monolayer.

It is pertinent that new limiting precursor systems are created by adding at least one limiter to the deposition process. In particular, precursors that are not self-limiting, or only to an inadequate degree, without limiters can be made self-limiting. Many limiters may also act with a greater self-limiting effect on a depositing process than other limiters. The degree of self-limiting deposition may also be dependent on the concentration of at least one limiter. In particular, a minimum concentration of a limiter may be necessary to achieve a self-limiting deposition. Thus, the number of precursor systems available for self-limiting deposition can be increased. This allows flexibility in the deposition of layers.

The deposition may comprise a contactless vaporizing system and method, using discontinuous injection of metal starting substances (precursors) that are liquid or mixed with limiters into a heated volume with subsequent transformation into the gas phase. This allows the precursors to be made available in the deposition system to the deposition process with high gas phase saturation. This can increase the growth rate and the throughput. Or some precursors or precursors mixed with limiters may be fed to the deposition process by a continuous vaporizing system and method or a bubbler-based system and method or a gas supply system and method. Altogether, the precursors can be fed in by one or more precursor feeding systems and methods. The precursors and limiters may be vaporized together or separately. If the precursors and limiters are vaporized separately, the precursors and limiters can be mixed in the gas phase.

In one example, ruthenium or ruthenium oxide layers were deposited. For this purpose, a metalorganic ruthenium precursor was in one case 1) mixed with octane, butyl acetates, tetrahydrofuran, methanol, ethanol, isobutyl amines, triethyl amines, butanol and/or cyclohexane and in a further case 2) was mixed with isooctane, dioxane, dimethylformamide, pyridine and/or toluene. The mixture was in each case vaporized and introduced with reactive oxygen-containing gas alternately and at separate times into a reaction chamber, in order to make it possible for ruthenium or ruthenium oxide layers to be deposited on a substrate. In experiments, the amount of the available precursor mixture was increased or decreased by certain factors. In case 1), the deposited thickness of the film increased or decreased correspondingly. In case 2), the deposited thickness of the film remained constant. The solvents in cases 1) and 2) control the degree of self-limiting deposition. With the solvents in case 2), self-limiting deposition can be achieved for example with the metalorganic ruthenium precursor. The metalorganic precursors may consist of two beta diketones and one diene coordinated with a ruthenium atom. The beta diketone may be 2,2,6,6-tetramethyl-3,5-heptanedionato and the diene may be 1,5-cyclooctadiene.

When isooctane, dioxane, dimethylformamide and toluene were used, substantially ruthenium was deposited as a result of introducing the vaporized precursor mixture and the reactive oxygen-containing gas alternately and at separate times into a reactor chamber. When pyridine was used, however, substantially ruthenium oxide was deposited under these conditions.

When isooctane, dioxane and dimethylformamide were used, substantially ruthenium oxide was deposited as a result of non-pulsed, continuous and simultaneous introduction of the reactive oxygen-containing gas with the vaporized precursor mixture into a reaction chamber. When toluene was used, however, substantially ruthenium was deposited under these conditions.

In another example, the deposition of zirconium oxide or hafnium oxide layers was investigated. For this purpose, a metalorganic zirconium or hafnium precursor was in one case 1) mixed with octane, butyl acetates, tetrahydrofuran, methanol, ethanol, isobutyl amines, triethyl amines, butanol and/or cyclohexane and in a further case 2) was mixed with isooctane, dioxane, dimethylformamide, pyridine and/or toluene. The mixture was in each case vaporized and introduced alternately and at separate times into a reactor chamber, in order to make it possible for zirconium oxide or hafnium oxide layers to be deposited on a substrate. In experiments, the amount of the available precursor mixture was increased or decreased by certain factors. In case 1), the deposited thickness of the film increased or decreased correspondingly. Self-limiting behavior could only be achieved within an inadequately narrow process window at average temperatures of approximately 300-360° C. (for Hf), approximately 280-350° C. (for Zr) and average precursor mixture pulsed lengths of approximately 0.8-1.2 s. In case 2), the deposited thickness of the film remained substantially constant even significantly below or above these ranges. The solvents in cases 1) and 2) control the degree of self-limiting deposition. With the solvents in case 2), self-limiting deposition can be achieved for example with the metalorganic zirconium or hafnium precursor. The metalorganic precursors may consist of two t-butoxides and two 1-methoxy-2-methyl-2-propanolate groups coordinated with a zirconium or hafnium atom or four 1-methoxy-2-methyl-2-propanolate groups coordinated with a zirconium or hafnium atom.

What is claimed is:

1. Process for depositing at least one layer, which contains at least one first component, on at least one substrate in a process chamber, first and second starting materials, of which at least the first starting material contains the first component, being introduced in gaseous form into the process chamber in a cyclically alternating manner, in order to deposit substantially only one layer at a time of the first component with every cycle, characterized in that a first starting material which does not intrinsically allow itself to be deposited in a self-limiting manner, or only within a narrow process window, is used, and, at the same time as or at a different time from the first starting material, a limiter formed of a hydrocarbon is introduced into the process chamber in such a way that the depositing of the first component on the substrate automatically ends after completion of the first layer.

2. Process according to claim 1, characterized in that the first starting material is a solid or liquid stored in a container and the limiter is in the same container.

3. Process according to claim 2, characterized in that the limiter and the first starting material form a solution.

4. Process according to claim 1, characterized in that the solution is an at least 0.01 molar solution.

5. Process according to claim 1, characterized in that the limiter is stored in a container separate from the first starting material.

6. Process according to claim 1, characterized in that the deposition takes place under a total pressure of 0.1 to ten torr.

7. Process according to claim 1, characterized in that the deposition takes place at a temperature of from 200° C. to 700° C.

8. Process according to claim 1, characterized in that the deposition takes place on a planar or highly structured substrate.

9. Process according to claim 8, characterized by deposition of a multi-component layer, at least one second component of a second starting material being introduced into the process chamber.

10. Process according to claim 1, characterized in that a second or third starting material is formed by a reactive gas, which is introduced into the process chamber alternately with the first starting material.

11. Process according to claim 1, characterized in that the limiter is introduced into the process chamber between the first and second starting materials.

12. Process according to claim 1, characterized in that the limiter is introduced into the process chamber together with the reactive gas.

13. Process according to claim 1, in that the starting materials are introduced into the process chamber in a pulsed manner.

14. Process according to claim 1, characterized by a liquid containing a first and/or a second component, which is introduced into the vaporizing chamber in a pulsed manner in order to be vaporized there without contact with the walls by merely heat absorption from the carrier gas located in the vaporizing chamber.

15. Process according to claim 14, characterized in that, between the pulses, merely a flow of inert carrier gas is introduced into the process chamber to purge the process chamber.

16. Process according to claim 1, characterized in that the process chamber is evacuated at least once every cycle.

17. Process according to claim 1, characterized in that the limiter is a material that is liquid or solid at room temperature and is vaporized in order to be introduced into the process chamber as a gas.

18. Process according to claim 1, characterized in that the limiter is introduced into the process chamber together with a carrier gas.

19. Process according to claim 1, characterized in that the delivery of the limiter takes place by means of a bubbler.

20. Process according to claim 1, characterized in that the limiter is transformed into the gas phase without contact by pulsed injection into a heated gas volume.

21. Process according to claim 1, characterized by starting materials and/or limiters that are gaseous already at room temperature.

22. Process according to claim 1, characterized in that the limiter consists of a mixture of materials.

23. Process according to claim 1, characterized in that the degree of self-limiting deposition is controlled by setting the concentration of at least one limiter.

24. Process according to claim 12, characterized in that the chemically reactive gases are oxygen compounds or nitrogen compounds and in that O2, O3, NO2, H2O or NH3 are used in particular.

25. Process according to claim 1, characterized in that the deposited layers consist of a number of components and are in particular insulating, passivating, semiconducting or electrically conducting.

26. Process according to claim 1, characterized in that a number of planar or highly structured substrates are disposed next to one another on at least one substrate holder, the substrate holder preferably rotating.

27. Process according to claim 1, characterized in that a number of planar and/or highly structured substrates are disposed in the process chamber in a vertically oriented manner one above the other or in a horizontally oriented manner one next to the other or inclined in relation to one another.

28. Process according to claim 1, characterized in that the first component is a metalorganic compound and contains in particular ruthenium, zirconium or hafnium.

29. Process according to claim 2, characterized in that the limiter is and/or contains isooctane, dioxane, dimethylformamide, pyridine and/or toluene.

30. Process for depositing at least one layer, which contains at least one first component, on at least one substrate in a process chamber, first and second starting materials, of which at least the first starting material contains the first component, being introduced in gaseous form into the process chamber in a cyclically alternating manner, in order to deposit substantially only one layer at a time of the first component with every cycle, characterized in that a metalorganic ruthenium, zirconium or hafnium compound which, under the process conditions, does not allow itself to be deposited in a self-limiting manner, or only within a narrow process window, is used, and, at the same time as or at a different time from the first starting material, octane, butyl acetates, tetrahydrofuran, methanol, ethanol, isobutyl amines, triethyl amines, butanol, cyclohexane, isooctane, dioxane, dimethylformamide, pyridine and/or toluene is introduced into the process chamber, so that the depositing of the first component on the substrate automatically ends after completion of the first layer.

31. Process according to claim 30, characterized in that the metalorganic starting material consists of two beta diketones and one diene coordinated with a ruthenium atom.

32. Process according to claim 31, characterized in that the beta diketone is 2,2,6,6-tetramethyl-3,5-heptanedionato.

33. Process according to claim 31, characterized in that the diene is 1,5-cyclooctadiene.

34. Process according to claim 30, characterized in that a mixture of a vaporized ruthenium starting material and isooctane, dioxane, dimethylformamide and/or toluene and a gas comprising reactive oxygen are introduced into a reactor chamber in an alternating manner and at different times in order to deposit substantially ruthenium.

35. Process according to claim 30, characterized in that a mixture of a vaporized ruthenium starting material and pyridine and a gas comprising reactive oxygen are introduced into a reactor chamber in an alternating manner and at different times in order to deposit substantially ruthenium oxide.

36. Process according to claim 30, characterized in that a mixture of a vaporized ruthenium starting material and isooctane, dioxane and/or dimethylformamide is introduced into a reactor chamber at the same time as a reactive oxygen-containing gas in order to deposit substantially ruthenium oxide.

37. Process according to claim 30, characterized in that a mixture of a vaporized ruthenium starting material and toluene is introduced into a reactor chamber continuously and at the same time as a reactive oxygen-containing gas in order to deposit substantially ruthenium.

38. Process according to claim 30, characterized in that the first starting material consists of two t-butoxides and two 1-methoxy-2-methyl-2-propanolate groups coordinated with a zirconium or hafnium atom.

39. Process according to claim 30, characterized in that the first starting material is vaporized together with the limiter as a mixture and is introduced into a reactor chamber with a reactive oxygen-containing gas in an alternating manner and at different times in order to deposit ruthenium oxide, zirconium oxide or hafnium oxide layers on a substrate.
